(19) United States
(12) Patent Application Publication
(10) Pub. No.: US 2025/0323068 A1
(43) Pub. Date: Oct. 16, 2025

(54) APPARATUS FOR IMPROVED MATERIAL LIFT OFF (MLO)SEMICONDUCTOR PROCESSING

(71) Applicant: VEECO INSTRUMENTS INC., Plainview, NY (US)

(72) Inventors: Phillip Tyler, Horsham, PA (US); John Taddei, Marco Island, FL (US); Kevin Donnelly, Horsham, PA (US); Hunter Jones, Horsham, PA (US); Mark Yannuzzi, Horsham, PA (US)

(73) Assignee: VEECO INSTRUMENTS INC., Plainview, NY (US)

(21) Appl. No.: 19/174,188

(22) Filed: Apr. 9, 2025

Related U.S. Application Data
(60) Provisional application No. 63/633,279, filed on Apr. 12, 2024.

(51) Int. Cl. H01L 21/67; H01L 21/02; H01L 21/3213

(52) U.S. Cl. CPC H01L 21/6708; H01L 21/02068; H01L 21/32134

(57) ABSTRACT

An immersion station for performing lift off of metals and other materials (e.g., organic or inorganic films) from a plurality of wafers comprises an immersion chamber having a conical bottom portion, a drain coupled thereto, a spray bar having nozzles adapted to spray chemical solvent at a high flow rate into the immersion chamber, and an immersion tool positioned within the chamber having a cassette with compartments for holding a plurality of wafers, wherein the immersion tool has openings for exposure to the chemical solvent spray. The immersion tool and the spray bar nozzles are configured so as to provide an even distribution of solvent across the plurality of wafers in the cassette to induce metals to lift off from the plurality of wafers, and solvent and metal debris removed from the wafers flows downwardly to the conical bottom portion which directs the flow into the drain.

### CROSS-REFERENCE TO RELATED PATENT APPLICATIONS

This application is based on and claims priority to U.S. Provisional Patent Application 63/633,279, filed Apr. 12, 2024, the entire contents of which is incorporated by reference herein as if expressly set forth in its respective entirety herein.

### FIELD OF THE DISCLOSURE

The invention generally relates to semiconductor manufacturing, and more particularly relates to an apparatus, system and method for performing a material lift off utilizing a solvent based process.

### BACKGROUND OF THE DISCLOSURE

Metal lift-off is a semiconductor fabrication process that follows a metal deposition process over a patterned photoresist layer. In this process, the metal that is deposited between photoresist sections is intended to remain on the structure while the metal deposited over photoresist sections is intended to be removed (i.e., lifted off) when the resist is removed with a solvent.

Initial automated wet metal lift-off (MLO) processes were performed using wet benches. Wet bench toolsets required only low capital expenditures but suffered from a number of poor process performance metrics: incomplete material liftoff, low yield, high chemical usage, large hazardous waste creation, poor process repeatability, high defectivity and tool operator exposure to open baths of hazardous chemicals. Furthermore, lifted off materials accumulated in the bath resulting downtime and maintenance issues as the toolsets were not designed to handle these lifted materials. With the advent of high-volume manufacturing (HVM) of devices for defense and mobile communications a more robust MLO solution was required to ensure better performance. In the 1990s a two-step process was introduced. The first step of this process is a multi-wafer immersion step that is used to prepare the resist mask on the wafer for lift off. In a second step, the wet wafer is robotically transferred to a single wafer heated solvent high pressure spray (300-3,000 psi) chamber in which the lift-off occurs. The two-step method was quickly adopted and has held a dominant market share for HVM MLO ever since.

While the industry-dominant two-step MLO process has outperformed other methods for performing MLO, there are certain applications, such as soft-metal lift-off, where even the best known method could be improved upon. When soft metals (such as Au or Al) are exposed or connected to harder metals such as alumina (Al₂O₃) the lift off of harder material can cause scratching or damage to soft metal portions intended to remain on the wafer surface.

In view of challenges such as these, high-end toolsets enable process development for each lift off application and permit optimal “recipes” for lift off process to be created. The recipes have varied in terms of immersion times, spray pressure, arm motion and duration. When the optimal recipe is use for each wafer type, the best obtainable results are reached. However, the disadvantage of having numerous lift recipes is that the incorrect recipe could be run for a wafer type. The advantage of using a single lift-off process for all wafer types is that it eliminates the possibility of mistakenly running a recipe designed for a layer that is relatively easy to lift off on another layer that is relatively more difficult to lift off, which can result in incomplete lift off. Accordingly, when a single recipe is used for all wafer types it must be the recipe for the most difficult lift off process. The drawback of the single lift-off recipe for all wafer types is that the layers in which metal lifts off most easily tend to lift off in the immersion station rather than in the spin chamber as intended. The metals lifted off the immersion station accumulate and result in increased tool, maintenance and robotic handling errors.

In general, conventional immersion stations are not designed to handle the metal debris produced in many current fabrication processes. What is therefore needed is a metal lift-off process that performs well for special case applications such as soft metal lift-off, and which also solves the problems associated with debris removal.

### SUMMARY OF THE DISCLOSURE

In a first aspect, the present disclosure provides an immersion station for performing lift-off of metals from a plurality of wafers. The immersion station comprises an immersion chamber having a conical bottom portion, a drain coupled to the conical bottom of the immersion chamber, a spray bar coupled to the chamber having nozzles adapted to spray chemical solvent at a high flow rate into the immersion chamber, and an immersion tool positioned within the chamber having a cassette with compartments for holding a plurality of wafers, wherein the immersion tool has openings for exposure to the chemical solvent spray. The immersion tool and the spray bar nozzles are configured within the immersion chamber so as to provide an even distribution of solvent across the plurality of wafers in the cassette to induce metals to lift off from the plurality of wafers, and solvent and metal debris removed from the wafers flows downwardly to the conical bottom portion which directs the flow into the drain.

In a another aspect, the present disclosure provides a metal lift-off system comprising: 1) an immersion station including an immersion chamber, the immersion chamber including a conical bottom and a drain, a spray bar coupled to the chamber having nozzles adapted to spray chemical solvent at a high flow rate into the immersion chamber, and an immersion tool positioned adapted to for hold a plurality of wafers, wherein the immersion tooling has openings for exposure to the chemical solvent spray, and the spray bar nozzles provide an even distribution of solvent across the plurality of wafers in the immersion tool to lift off from the plurality of wafers, and wherein solvent and metal debris removed from the wafers flows downwardly to the conical bottom portion which directs the flow into the drain; 2) a solvent recirculation system coupled to the spray bar, recirculation nozzles and drain of the immersion chamber, the recirculation system including a pump that adapted to provide a stream of clean solvent under pressure and to permanently remove debris from the metal lift-off system; and 3) a high-pressure spray chamber adapted to receive a wafer transferred from the immersion station, the spray chamber having a high-pressure sprayer for spraying solvent at a high pressure onto the transferred wafer so as to remove any metal or other debris remaining on the wafer after lift-off in the immersion chamber.

In a further aspect, a method of performing lift-off of metals from a plurality of wafers. The method comprises placing wafers at discrete intervals into tooling that once fully loaded as prescribed in the process recipe will be holding the plurality of wafers within an immersion chamber subjecting the plurality of wafers within the immersion chamber to a high flow rate spray of solvent, inducing a majority of metal on the surface of the wafers to lift off within the immersion chamber, transferring wafers individually to a high-pressure spray chamber, and spraying an individual wafer in the high-pressure spray chamber to remove any remaining metal or debris on the wafer.

These and other aspects, features, and advantages can be appreciated from the following description of certain embodiments and the accompanying drawing figures and claims.

### BRIEF DESCRIPTION OF THE DRAWINGS

FIG. 1 is a vertical cross-sectional view of an embodiment of an immersion station for high flow immersion lift-off according to the present disclosure.

FIG. 2A is a cross-sectional view of an immersion chamber according to an embodiment of the present disclosure without presence of the immersion tool.

FIG. 2B is a perspective view of an embodiment of an immersion chamber according to the present disclosure.

FIG. 2C is a top plan view of an embodiment of an immersion chamber according to the present disclosure.

FIG. 3 is an embodiment of a solvent recirculation system for providing high pressure and/or high velocity solvent flow through an immersion station according to the present disclosure.

### DESCRIPTION OF CERTAIN EMBODIMENTS OF THE DISCLOSURE

The present disclosure describes an apparatus and method for performing a metal lift-off (MLO) or organic film strip process through a multi-step sequence that includes a high flow immersion (HFI) step followed by high pressure and/or high velocity spray in a single-wafer spin chamber.

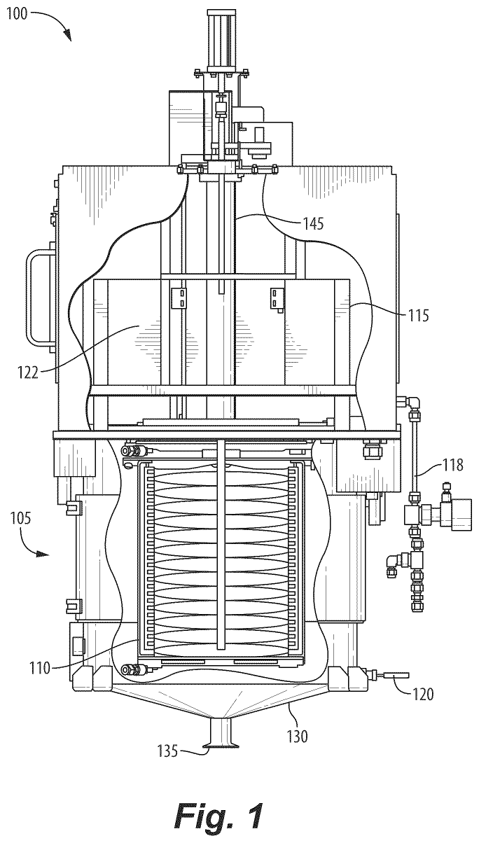

FIG. 1 is a vertical cross-sectional view of an embodiment of an immersion station 100 according to an embodiment of the present disclosure. The station includes an immersion chamber 105 into which an immersion tool 110 can be inserted (by being lowered into the chamber) and removed (by being raised out of the chamber). The immersion tool 110 comprises a container, or cassette, that securely holds multiple substrates (e.g., wafers, masks, frames, etc.) during high-flow immersion of chemical solvent for metal or organic material lift off. The immersion tool 110 is configured and positioned so that the substrates remain at a minimum angle to index the wafers toward their resting position at the back of the immersion tooling. Furthermore, the immersion tool 110 is designed to permit a high flow of solvent to be distributed through the cassette evenly. This measure permits lifted materials to flow through the tooling and prevents accumulation of debris on the wafers. The even distribution of fluid across the wafers is achieved, at least in part, by making the pitch of the individual wafer carriers in the cassette further apart than in conventional cassettes, and by removing some portions of the conventional cassette to permit more open flow.

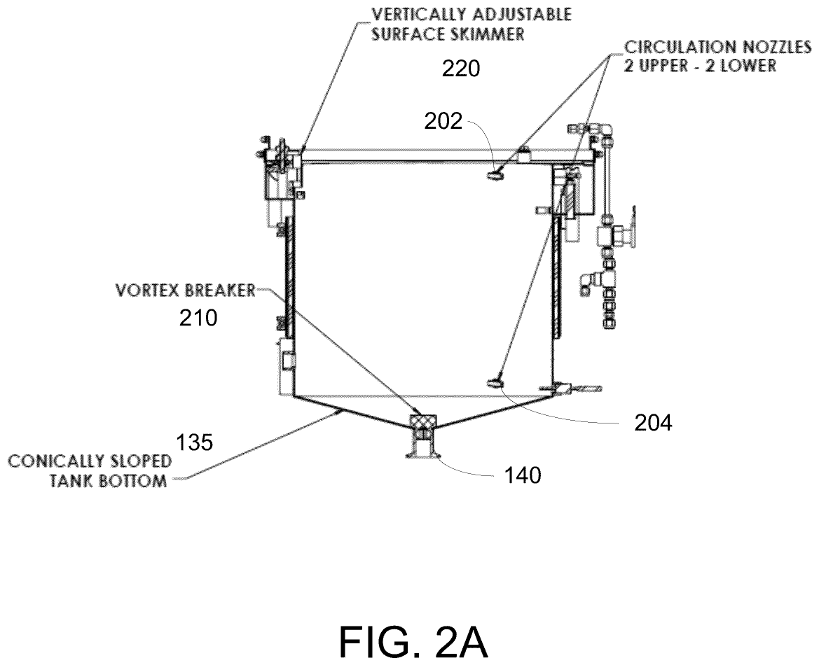

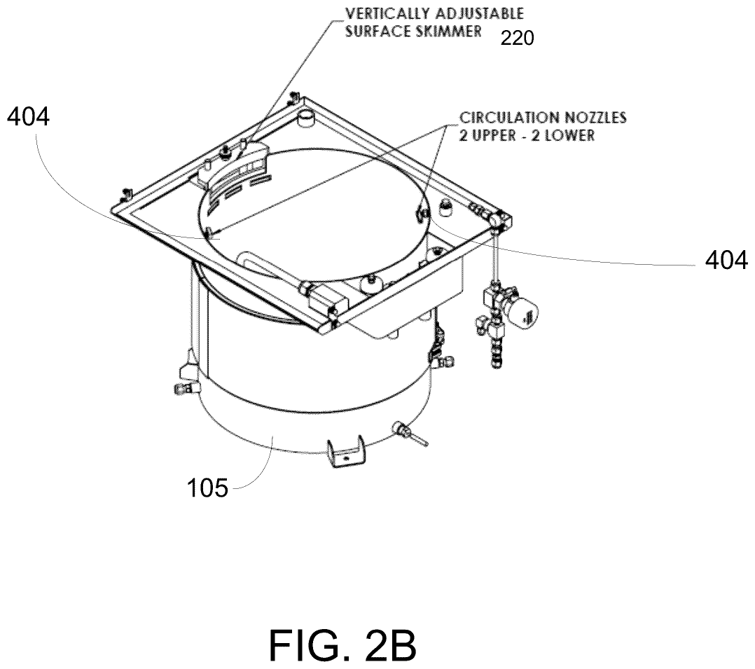

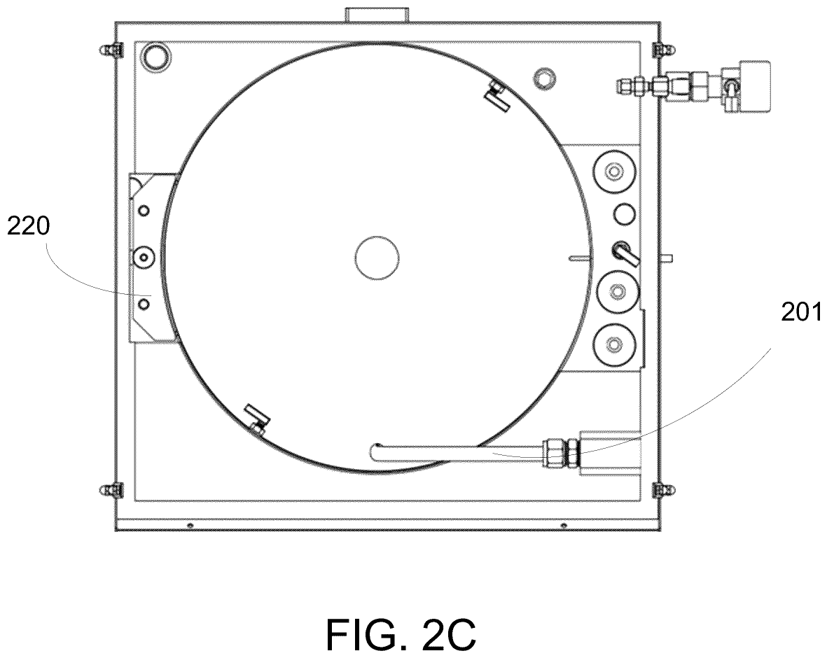

A spray bar 201 (shown in FIG. 2C) including one or more nozzles delivers solvent onto the immersion tool. The volume and velocity of the solvent flowing over the wafers in the immersion tool 110 is set at a level to promote the desired material removal of debris and to influence any liberated materials to flow off of the nested wafers. Solvent flow rates of up to 20 LPM have proven to be effective. The immersion chamber 105 is also designed to channel the high flow rate of solvent and any lifted metals and debris toward the bottom of the immersion station under the force of both the solvent flow and gravity. More specifically, the immersion chamber includes a conically shaped bottom portion 130. In certain embodiments, the conically shaped bottom 130 is designed with a 15-degree angle, which has been demonstrated to be optimal for inducing large pieces (>20 micron) of lifted materials such as metals, dielectrics, organic etch residues, fluxes, plasma related fluorocarbon, etc. to flow down through the bottom section into a drain 135 at a steady rate of high flow (e.g., 20 liters per minute (LPM). The drain 135 is preferably positioned at the center of the bottom of the chamber. A thermocouple 120 is coupled to the immersion chamber 105 and used to monitor the temperature therein.

The immersion station 100 also includes a headspace section 115 having an inlet 118 through which a nitrogen purge gas is introduced. The nitrogen gas serves to keep fab air, and associated moisture and defects out of the immersion station, extending chemical life and eliminating corrosion due to water build up in the recycled chemicals used in the immersion station. The headspace section 115 also includes a manual access window 122 through which operator access can be made available to the immersion station and chamber. The headspace section further includes an input cassette elevator 145 which is adapted to raise and lower the cassette of the immersion tool 110. The elevator 145 is located to one side as to enable an operator an unobstructed path to reach the manual access window 122. The manual access window 122 permits the immersion tool 110 to be swapped out and replaced.

FIG. 2A is a cross-sectional view of an immersion chamber 105 according to an embodiment of the present disclosure without the immersion tool present. As shown, two sets of circulation nozzles are included in the chamber for the spraying of solvent within the chamber. A first set of nozzles 202 is positioned in an upper section of the chamber, and a second set of circulation nozzles 204 is positioned in a lower section of the chamber. In certain embodiments each of the nozzle sets 202, 204 can include two distinct nozzles, but in other embodiments the number of nozzles in each set can be higher or lower. The sprays from the top and bottom sets of nozzles 202, 204 can create a swirling action around the sidewall of the chamber. This swirling action induces a whirlpool effect to assist in dislodging and removing any small debris that has accumulated over time. The inlet to the drain 135 has a vortex breaker 210 to inhibit vortex creation in the drain.

A vertically adjustable surface skimmer 220 is positioned at the top of the immersion chamber and is movable horizontally to skim off materials that are floating on fluids at the top of the immersion chamber. A perspective view of the immersion chamber shown in FIG. 2B shows the skimmer 220 and also shows an exemplary spacing of the two nozzles 404,408 in the first set located in the upper portion of the immersion chamber. The upper nozzles 404, 408 can provide a swirling flow that is parallel to the immersion chamber internal sidewall. FIG. 2C is a top plan view of the embodiment of the immersion chamber shown in FIGS. 2A and 2B and clearly illustrates the spray bar 201 which extends from the top of the immersion chamber downwards toward the position of the immersion tool so as to provide an even distribution of solvent across the wafers in the cassette of the immersion tool.

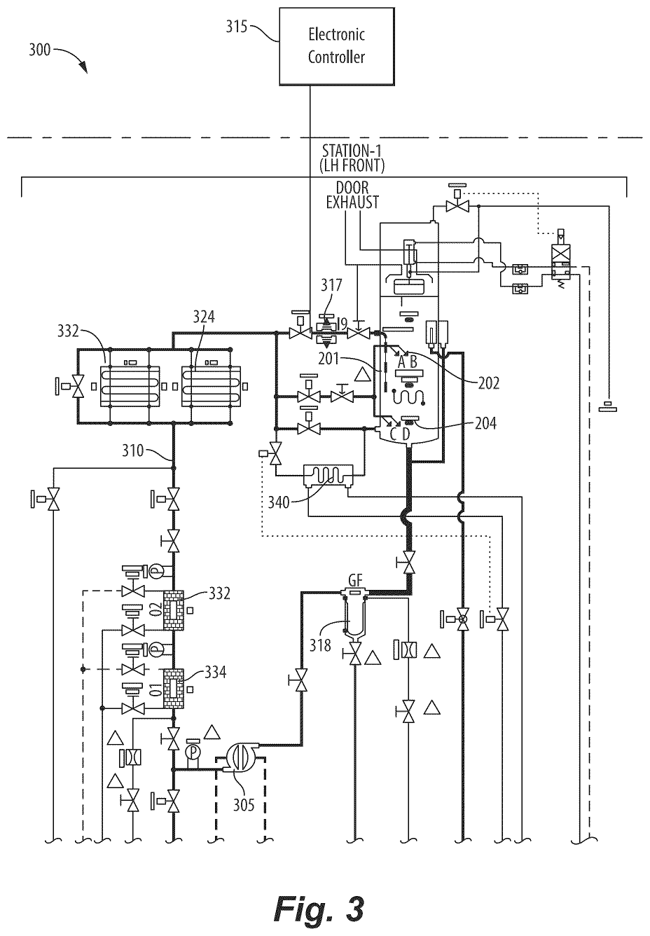

The flow of solvent through the immersion station is performed by a solvent recirculation system schematically illustrated in FIG. 3. The recirculation system 300 includes a pump 305 that is adapted to deliver and recycle solvent through a circulation line 310 into and out of the immersion chamber 105. An electronic controller 315 monitors the flow through flow meter 317 and then regulates the pump to provide a selected flow rate of fluid flow (up to 20 LPM) using programmed open or closed-circuit control and monitored parameters. A spray bar 201 coupled to the circulation line and to the immersion chamber 110 is positioned to distribute flow across the wafers evenly distribution through the length of the immersion tool 110 so that all wafers being processed are exposed to the same conditions. A large-capacity filter 318 is positioned below the drain of the immersion chamber so as to capture materials outlet from the drain. The filter 318 preferably has a pore size in the 1-50 um range and is a cost-efficient bag type filter with sufficient volume to operate for long periods of time (e.g., 7-90 days). Precious metals are captured for recovery and a new filter element can quickly be removed and replaced.

Heaters 322, 224 are positioned along the circulation line 210 to regulate the temperature of the solvent. Additional filters 332, 334 are positioned along the circulation line 210 to remove particulates of certain sizes as the fluid passes through the filters. The solvent is thus heated, filtered and pumped through the recirculation system.

The immersion station and chamber are designed to eliminate the lifted material from building up via the high fluid flow pressure and velocity, and as well as design adjustments that promote skimming and draining of debris. However, the fluid occasionally requires to be completely drained out of the station, either for maintenance or because the chemical bath has exceeded its permissible life and needs to be changed. Prior to draining the immersion station of solvent, the fluid is circulated through a cooling coil 340 to lower the temperature of the solvent in the recirculation loop. The cooled solvent in turn lowers temperatures of immersion chamber upon entry. During this period a self-cleaning sequence is performed by the immersion tool 110. The distribution of fluid through the distribution manifold is stopped and redirected at high pressure/velocity to the sets of recirculation nozzles 202 204, in sequence, that deliver flow parallel to the immersion tank sidewall. This dual sequence of upper and then lower swirling flows is set at sufficient volume, velocity and direction to motivate any debris of less than about 20 microns to flow down into the drain 135. The swirling flows are desired to create turbulent flow to induce debris to flow to the drain; however it is not desirable to have a vortex form in the drain. Accordingly a vortex breaker 210 has been installed at the drain inlet at the bottom of the high flow immersion chamber.

As noted above, the volume and velocity of the solvent flowing over the wafers is selected to promote the desired material removal by forcing liberated materials to flow off of the nested wafers toward the bottom of the immersion chamber where the conically shaped bottom 130 induces the removed materials to flow into the drain 140 with steady state high flow (e.g., 20 LPM). The drain is of sufficient size for debris to self-drain out of the immersion chamber.

During the metal lift-off process, the wafers in the immersion tool and chamber are exposed to the desired flow of heated solvent. The flow of solvent is maintained over the wafers for a required duration until a high percentage of the targeted material (metal, organic material) is lifted within the immersion chamber. The percentage of removal depends upon the pattern, resist mask and thickness of films in the substrate stack. Generally, immersion alone is insufficient to completely lift off one hundred percent of the targeted material and to remove other undesired debris from the wafer surface.

Therefore, to complete the lift-off immersion is followed by an aggressive spray process. Wafers are transported individually while wet into a solvent spray chamber distinct from the immersion chamber. If the wafer is simply rinsed and dried it can be impacted negatively from un-lifted metals and related defects permanently adhering to the wafer surface and reducing its yield of good devices. Accordingly, while the wafer remains wet with solvent from the immersion station it is processed with a high-pressure spray to dislodge and remove stubborn metals. A high-pressure spray (300-3000 PSI) is produced via a pump. The pumped fluid is provided at an extremely high but precision-controlled pressure and is dispensed at design temperature. The temperature is controlled to near but below the flashpoint for heated solvents and the raised temperature enhances the process effectiveness of the solvent. This process removes materials and defects that are adhered to but do not belong on the surface of the wafer. Since the vast majority of the metal is lifted in the initial phase in the immersion chamber, there is only a small amount left on the wafer. This permits the final lift off materials to pass off of the wafer without causing damage or scratching to the soft metals that remain on the wafer surface.

In some instances, a high velocity spray will be preferred over a high-pressure spray. For example, an aggressive high velocity solvent (HVS) spray can be used in place of a high-pressure spray (HPC) for purposes of chemical compatibility, to provide an alternate spray pattern or force deliverable. The high velocity dispense is an aggressive spray that utilizes pressurized nitrogen (up to 75 psi) to accelerate low pressure, heated solvent through a nozzle. The combination of solvent and nitrogen sharing a shaped nozzle delivers a matrix of fluid qualities in terms of droplet size, fluid velocity, dispense size and shape at wafer impact. There is overlap in aggressiveness between HPC (high pressure spray) and HVS (high velocity spray) dispense, with the high velocity spray having a range below the lower end of the HPC, as the HPC pump typically has a minimum setpoint of approximately 300 psi in most implementations. HVS also has the advantage that is can be implemented at lower capital and maintenance costs in comparison to HPC as it does not require a high-pressure pump, can perform cleaner fluid dispensing with increased chemical compatibility. The high velocity wetted path can be non-metallic and can thus use chemistries that are incompatible with 316SS, with which the high pressure wetted path (pump, tuning, tanks and dispense nozzle) are typically fabricated. A disadvantage of HVS in comparison to HVC is that the nitrogen utilized to accelerate the fluid through the dispense nozzle tip tends expand at the nozzle tip exit. The expanding nitrogen undergoes the Joules-Thompson effect and cools as it expands at atmospheric pressure. This in turn cools the solvent dispense which can reduce rates of chemical processing.

The force of either the HPC or HVS at the nozzle tip is proportional to the force of impact of the spray on the wafer. HPC can generate higher forces at the nozzle tip and operate with a non-expanding spray pattern. Accordingly, a maximal force per unit area can be obtained with a high-pressure spray. In certain circumstances, the maximal force is process enabling and recommended. In other processes involving fragile materials or structures that can be damaged by use maximal force, a less aggressive spray process such as HVS is preferred. A reduced force generated at the nozzle tip is associated with an expanding dispense contact zone which spreads an already-reduced force over a greater area, further reducing force per unit area.

After spraying with the proper force per unit area to obtain deaired results, the wafer can undergo spinning, rinsing and drying in the same chamber. Alternatively, the wafer can be retransferred wet into a separate spin, rinse, dry (SRD) chamber. Separating the SRD from the HVS processes permits higher solvent recycling rates through eliminating rinse fluid which would otherwise need to be purged from the chamber prior to recycling of solvent on the next wafer processed. Separate SRD also extends solvent bath life by avoiding contamination with water. In a dedicated SRD chamber the wafers generally exit with lower defectivity levels.

The processes described herein can be controlled using one or more electronic or computing devices (e.g., electronic control units, processor, etc.). Each such device typically includes a control unit or processor (or multiple processors) that executes program instructions or modules stored in a memory or other non-transitory computer-readable storage medium or device (e.g., solid state storage devices, disk drives, etc.). The various functions disclosed herein may be embodied in such program instructions, or may be implemented in application-specific circuitry (e.g., ASICs or FPGAs). The methods described in connection with the embodiments disclosed herein can be embodied directly in hardware, in a software module executed by a processor device, or in a combination of the two. A software module can reside in RAM memory, flash memory, ROM memory, EPROM memory, EEPROM memory, registers, hard disk, a removable disk, a CD-ROM, or any other form of a non-transitory computer-readable storage medium.

It is to be understood that any structural and functional details disclosed herein are not to be interpreted as limiting the systems and methods, but rather are provided as a representative embodiment and/or arrangement for teaching one skilled in the art one or more ways to implement the methods.

It is to be further understood that like numerals in the drawings represent like elements through the several figures, and that not all components and/or steps described and illustrated with reference to the figures are required for all embodiments or arrangements.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

Terms of orientation are used herein merely for purposes of convention and referencing and are not to be construed as limiting. However, it is recognized these terms could be used with reference to a viewer. Accordingly, no limitations are implied or to be inferred.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

While the disclosure has been described with reference to exemplary embodiments, it will be understood by those skilled in the art that various changes may be made and equivalents may be substituted for elements thereof without departing from the scope of the disclosed invention. In addition, many modifications will be appreciated by those skilled in the art to adapt a particular instrument, situation or material to the teachings of the disclosure without departing from the essential scope thereof. Therefore, it is intended that the invention not be limited to the particular embodiment disclosed as the best mode contemplated for carrying out this invention, but that the invention includes all embodiments falling within the scope of the appended claims.

What is claimed is:

1. A immersion station for performing lift off of metals from a plurality of wafers comprising:
an immersion chamber having a conical bottom portion;
a drain coupled to the conical bottom of the immersion chamber;
a spray bar coupled to the chamber having nozzles adapted to spray chemical solvent at a high flow rate into the immersion chamber; and
an immersion tool positioned within the chamber having a cassette with compartments for holding a plurality of wafers, wherein the immersion tool has openings for exposure to the chemical solvent spray;
wherein the immersion tool and the spray bar nozzles are configured within the immersion chamber so as to provide an even distribution of solvent across the plurality of wafers in the cassette to induce metals to lift off from the plurality of wafers; and
wherein solvent and metal debris removed from the wafers flows downwardly to the conical bottom portion which directs the flow into the drain.

2. The immersion station of claim 1, further comprising a headspace section coupled to a top of the immersion chamber having an elevator coupled to the immersion tool and operative to lower the immersion tool into the immersion chamber and life the immersion tool out of the immersion chamber.

3. The immersion station of claim 1, further comprising a first set of circulation nozzles for self-cleaning positioned in an upper part of the immersion chamber, and a second set of circulation nozzles for self-cleaning positioned in a lower part of the immersion chamber, wherein the first and second set of nozzles generate a spray that swirls around walls of the immersion chamber.

4. The immersion station of claim 1 further comprising a skimmer positioned at a top portion of the immersion chamber adjustable in a vertical direction and movable in a horizontal direction so as to remove buoyant debris from the immersion chamber.

5. The immersion station of claim 1, further comprising a vortex breaker positioned within the drain of the immersion chamber.

6. The immersion station of claim 1, wherein the high flow rate ranges from 10 liters per minute to 55 liters per minute.

7. A metal lift-off system comprising:
an immersion station including an immersion chamber, the immersion chamber further including a conical bottom section, a drain coupled to the conical bottom, a spray bar coupled to the chamber having nozzles adapted to spray chemical solvent at a high flow rate into the immersion chamber, and an immersion tool positioned adapted to for hold a plurality of wafers, wherein the immersion tool has openings for exposure to the chemical solvent spray, wherein the spray bar nozzles provide an even distribution of solvent across the plurality of wafers in the immersion tool to lift off from the plurality of wafers; and wherein solvent and metal debris removed from the wafers flows downwardly to the conical bottom portion which directs the flow into the drain;
a solvent recirculation system coupled to the spray bar, recirculation nozzles and drain of the immersion chamber, the recirculation system including a pump that adapted to provide a stream of clean solvent under pressure and to remove permanently remove debris from the metal lift-off system;
a high-pressure spray chamber adapted to receive a wafer transferred from the immersion station, the spray chamber having a high-pressure sprayer for spraying solvent at a high pressure onto the transferred wafer so as to remove any metal or other debris remaining on the wafer after lift-off in the immersion chamber.

8. The metal lift-off system of claim 7, wherein the recirculation system includes a recirculation line that receives solvent from the drain of the immersion chamber and a heater coupled to the recirculation line adapted to heat solvent that passes through the recirculation before the solvent is forced by the pump back to the immersion chamber.

9. The metal lift-off system of claim 7, wherein the recirculation system includes at least one filter coupled to the recirculation line and adapted to remove particulates from the stream of solvent received from the drain of the immersion chamber.

10. A method of performing lift off of metals from a plurality of wafers comprising:
placing wafers at discrete intervals into tooling that once fully loaded as prescribed in the process recipe holds the plurality of wafers within an immersion chamber;
subjecting the plurality of wafers within the immersion chamber to a high flow rate spray of solvent, inducing a majority of metal on the surface of the wafers to lift off within the immersion chamber;
transferring wafers individually to a high-pressure spray chamber; and
spraying an individual wafer in the high-pressure spray chamber to remove any remaining metal or debris on the wafer.

11. The method of claim 10, further comprising:
removing solvent containing metal removed from the wafers from the immersion chamber; and
filtering particulates from the removed solvent;
recirculating filtered solvent to the immersion chamber.

12. The method of claim 11, further comprising cleaning the immersion chamber using spray from nozzles positioned at upper and lower sections of the immersion chamber, wherein the spray from the nozzles positioned at the upper and lower sections creates a swirling effect within the immersion chamber.

13. The method of claim 11, further comprising skimming a surface of the immersion chamber to remove any floating debris.
